(19) United States
(12) Patent Application Publication
(10) Pub. No.: US 2024/0381683 A1
(43) Pub. Date: Nov. 14, 2024

(54) LIGHT EMITTING ELEMENT AND DISPLAY DEVICE

(71) Applicant: Sharp Display Technology Corporation, Kameyama City, Mie (JP)

(72) Inventors: Yoshihiro UETA, Kameyama City, Mie (JP); Takayuki NAKA, Kameyama City, Mie (JP)

(21) Appl. No.: 18/686,493

(22) PCT Filed: Oct. 25, 2021
(86) PCT No.: PCT/JP2021/039360

§ 371 Date: Feb. 26, 2024

(51) Int. Cl. H10K 50/115; H10K 50/16

(52) U.S. Cl. CPC H10K 50/115; H10K 50/16

(57) ABSTRACT

A light-emitting element includes a first electrode and a second electrode, a light-emitting layer disposed between the first electrode and the second electrode, and a charge function layer disposed between the light-emitting layer and the second electrode. The light-emitting layer includes a quantum dot layer including a plurality of quantum dots, and the charge function layer includes a nanoparticle layer including a plurality of nanoparticles. An average particle diameter of the plurality of nanoparticles is larger than an average particle diameter of the plurality of quantum dots.

### TECHNICAL FIELD

The disclosure relates to a light-emitting element and the like.

### BACKGROUND ART

PTL 1 discloses a light-emitting element including a light-emitting layer including quantum dots, and a charge transport layer including metal nanoparticles.

### CITATION LIST

### Patent Literature

PTL 1: JP2021-523530 T

### SUMMARY

### Technical Problem

In a known light-emitting element, there is room for improvement in luminous efficiency.

### Solution to Problem

A light-emitting element according to an aspect of the disclosure includes a first electrode, a second electrode, a light-emitting layer disposed between the first electrode and the second electrode, and a charge function layer disposed between the light-emitting layer and the second electrode. The light-emitting layer includes a quantum dot layer including a plurality of quantum dots, the charge function layer includes a nanoparticle layer including a plurality of nanoparticles, and an average particle diameter of the plurality of nanoparticles is larger than an average particle diameter of the plurality of quantum dots.

### Advantageous Effects of Disclosure

According to an aspect of the disclosure, luminous efficiency of a light-emitting element is improved.

### BRIEF DESCRIPTION OF DRAWINGS

FIG. 1 is a cross-sectional view illustrating a configuration example of a light-emitting element according to a first embodiment.

FIG. 2 is a graph showing a particle diameter distribution of a plurality of quantum dots in a quantum dot layer.

FIG. 3 is a graph showing a particle diameter distribution of a plurality of nanoparticles in a nanoparticle layer.

FIG. 4 is a band diagram of the light-emitting element.

FIG. 5 is a graph showing external quantum efficiency of the light-emitting element.

FIG. 6 is a schematic cross-sectional view illustrating actions of a light-emitting element according to a comparative example.

FIG. 7 is a schematic cross-sectional view illustrating actions of the light-emitting element according to the first embodiment.

FIG. 8 is a cross-sectional view illustrating a configuration of the light-emitting element according to the comparative example.

FIG. 9 is a cross-sectional view illustrating a configuration of the light-emitting element according to the first embodiment.

FIG. 10 is a schematic view illustrating surface roughnesses (Rms) of the nanoparticle layer and the quantum dot layer.

FIG. 11 is a schematic view illustrating a configuration example of the quantum dot.

FIG. 12 is a schematic view illustrating a configuration example of the quantum dot.

FIG. 13 is a flowchart illustrating a manufacturing method of the light-emitting element according to the first embodiment.

FIG. 14 is a set of cross-sectional views each illustrating the manufacturing method of the light-emitting element according to the first embodiment.

FIG. 15 is a graph showing an example of a particle diameter distribution in a nanoparticle solution.

FIG. 16 is a graph showing an example of the particle diameter distribution in a nanoparticle solution.

FIG. 17 is a graph showing a relationship between the Mg composition and the minor axis in zinc magnesium oxide nanoparticles.

FIG. 18 is a graph showing a relationship between the Mg composition and the density in the zinc magnesium oxide nanoparticles.

FIG. 19 is a schematic view illustrating a change in the shape of the zinc magnesium oxide nanoparticle when the magnesium composition is increased.

FIG. 20 is a cross-sectional view illustrating a configuration example of a light-emitting element according to a second embodiment.

FIG. 21 is a cross-sectional view illustrating another configuration example of the light-emitting element according to the second embodiment.

FIG. 22 is a cross-sectional view illustrating a configuration example of a light-emitting element according to a third embodiment.

FIG. 23 is a cross-sectional view illustrating a configuration example of the light-emitting element according to the third embodiment.

FIG. 24 is a cross-sectional view illustrating a configuration example of a display device according to a fourth embodiment.

### DESCRIPTION OF EMBODIMENTS

### First Embodiment

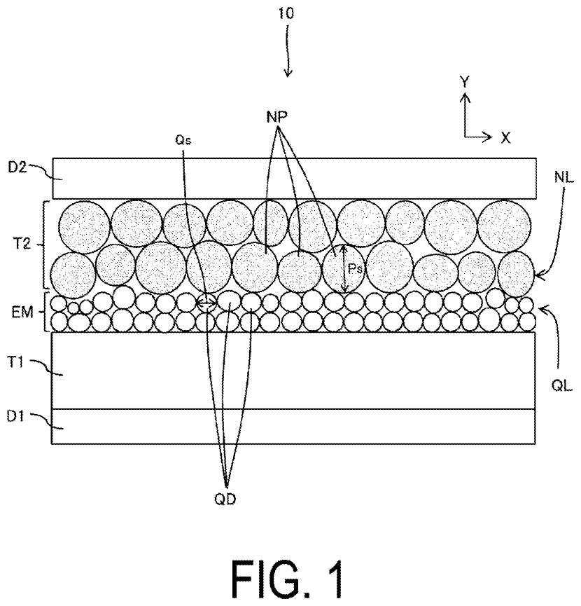

FIG. 1 is a cross-sectional view illustrating a configuration example of a light-emitting element according to a first embodiment. A light-emitting element 10 according to the first embodiment includes a first electrode D1, a second electrode D2, a light-emitting layer EM disposed between the first electrode D1 and the second electrode D2, a charge function layer T1 disposed between the first electrode D1 and the light-emitting layer EM, and a charge function layer T2 disposed between the light-emitting layer EM and the second electrode D2. The second electrode D2 is located in a layer above the first electrode D1. In other words, in terms of timing, the second electrode D2 is formed in a process performed subsequently to the forming of the first electrode D1. For example, the second electrode D2 is arranged at a position spatially farther than the first electrodes D1 with respect to a pixel circuit substrate (described later) including a thin film transistor.

The first electrode D1 may be an anode, the second electrode D2 may be a cathode, and the charge transport layer T2 may be an electron transport layer (ETL). A hole injection layer (HIL) may be provided between the anode and a hole transport layer, and an electron injection layer (EIL) may be provided between the cathode and the electron transport layer.

The light-emitting layer EM includes a quantum dot layer QL including a plurality of quantum dots QD, the charge function layer T2 includes a nanoparticle layer NL including a plurality of nanoparticles NP, and the quantum dot layer QL and the nanoparticle layer NL are adjacent to each other. The nanoparticle layer NL and the quantum dot layer QL may be in contact with each other. For example, there may be a gap between the nanoparticle layer NL and the quantum dot layer QL. The gap may be, for example, approximately 1 nm. Further, a plurality of discontinuous gaps may be present between the quantum dot layer QL and the nanoparticle layer NL, and the shapes of the gaps may be non-uniform shapes.

In the light-emitting layer EM, positive holes from the anode and electrons from the cathode are recombined, and excitons generated by the recombination return to a ground state to generate light. The recombination occurs in the light-emitting layer EM by applying a voltage (causing charges to flow) between the anode and the cathode.

Semiconductor nanocrystal particles having a light-emitting function can be used as the quantum dots QD. The quantum dot QD may emit light having a wavelength corresponding to the band gap, as electroluminescence. The band gap changes in accordance with the particle diameter and the composition of the quantum dot QD. The particle diameter of the quantum dot QD is, for example, 0.5 (nm) to 100 (nm), and may be 1.0 (nm) to 10 (nm). The shape of the quantum dot QD is not limited to a spherical shape (circular cross-sectional shape), and may be, for example, a polygonal cross-sectional shape, a rod-like three dimensional shape, a branch-like three dimensional shape, an ellipsoidal shape, a polyhedral shape, a rod-like shape, a branched three dimensional shape, a three dimensional shape having surface irregularities, or a shape obtained by combining these three dimensional shapes. The quantum dot QD may be a semiconductor fine particle having a particle diameter equal to or less than 100 nm, and may include at least one crystal selected from the group II-VI semiconductor compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe, the group III-V semiconductor compounds such as GaAs, GaP, InN, InAs, InP, and InSb, and the group IV semiconductor compounds such as Si and Ge. The diameter of a circle having the same area as the cross-sectional area of the nanoparticle NP can be used as the particle diameter of the nanoparticle NP, and the diameter of a circle having the same area as the cross-sectional area of the quantum dot QD can be used as the particle diameter of the quantum dot QD.

As the nanoparticle NP of the charge function layer T2, for example, a metal oxide particle having an electron transport function can be used. Like the quantum dot QD, the shape of the nanoparticle NP is not particularly limited. The shape is not limited to a spherical shape (circular cross-sectional shape), and may be, for example, a polygonal cross-sectional shape, a rod-like three dimensional shape, a branch-like three dimensional shape, an ellipsoidal shape, a polyhedral shape, a rod-like shape, a branched three dimensional shape, a three dimensional shape having surface irregularities, or a shape obtained by combining these three dimensional shapes. The metal oxide constituting the nanoparticle NP may contain one or more metal elements selected from the group I and group II metal elements, the crystal structure of the metal oxide may be cubic or hexagonal, and the metal oxide may be zinc oxide, zinc magnesium oxide, or zinc lithium oxide. The particle diameter of the nanoparticle NP may be, for example, 2.0 (nm) to 100 (nm).

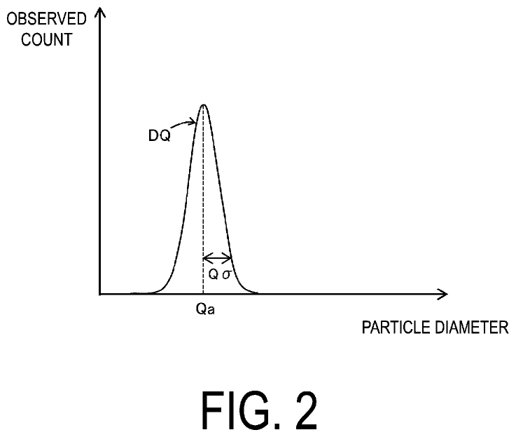

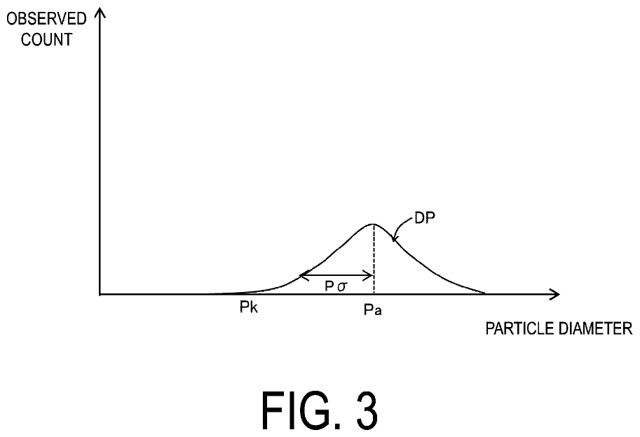

FIG. 2 is a graph showing a particle diameter distribution of the plurality of quantum dots in the quantum dot layer. FIG. 3 is a graph showing a particle diameter distribution of the plurality of nanoparticles in the nanoparticle layer. As illustrated in FIG. 1 to FIG. 3, in the present embodiment, an average particle diameter Pa of the plurality of nanoparticles NP in the nanoparticle layer NL is larger than an average particle diameter Qa of the plurality of quantum dots QD in the quantum dot layer QL. For example, Pa/Qa>1.5 may be satisfied.

Pσ>Pa/4 may be satisfied, where the standard deviation of a particle diameter distribution DP of the nanoparticles NP included in the nanoparticle layer NL is Pσ. Pσ/Pa>Qσ/Qa may be satisfied, where the standard deviation of a particle diameter distribution DQ of the quantum dots included in the quantum dot layer QL is Qσ. In other words, the coefficient of variation of the particle diameter distribution DP may be larger than the coefficient of variation of the particle diameter distribution DQ. A lower limit value (minimum particle diameter) Pk of the particle diameter distribution DP of the nanoparticles included in the nanoparticle layer NL may be 0.1×Pa or more, 0.3×Pa or more, or 0.5×Pa or more.

In FIG. 2 and FIG. 3, since the particle diameter distributions DP and DQ are close to a normal distribution, the mode (peak) of the particle diameter distribution DP is substantially the same as the average particle diameter Pa, and the mode of the particle diameter distribution DQ is substantially the same as the average particle diameter Qa, but the configuration is not limited to this example.

The particle diameter distributions DQ and DP in FIG. 2 and FIG. 3 can be obtained, for example, by observing cross sections of the light-emitting layer EM and the charge transport layer T2 using a transmission electron microscope (TEM) or the like and examining the particle diameters of a plurality (for example, 10 to 100) of the quantum dots QD and the particle diameters of a plurality (for example, 10 to 100) of the nanoparticles NP. When the mode of the particle diameter distribution DP is greater than the mode of the particle diameter distribution DQ, it may be regarded that the average particle diameter Pa is greater than the average particle diameter Qa. In a cross-sectional TEM image, a plurality of discontinuous gaps may be present between the quantum dot layer QL and the nanoparticle layer NL, and the shapes of the gaps may be non-uniform shapes.

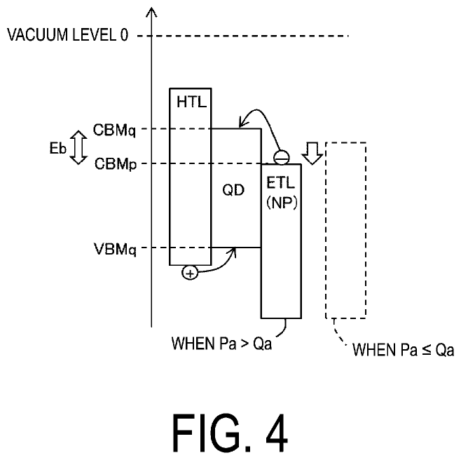

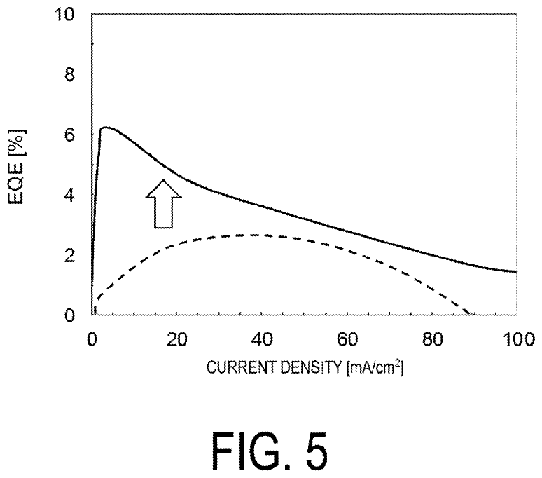

FIG. 4 is a band diagram of the light-emitting element. FIG. 5 is a graph showing external quantum efficiency of the light-emitting element. In the light-emitting element 10 illustrated in FIG. 1 to FIG. 3, since the nanoparticle layer NL has a particle diameter distribution equal to or greater than that of the adjacent quantum dot layer QL, the interface between the two layers (NL and QL) becomes non-uniform, and the number of contact points (charge transport paths) between the nanoparticles NP and the quantum dots QD decreases.

Furthermore, since the average particle diameter Pa of the nanoparticle layer NL is made larger (than the average particle diameter Qa of the quantum dot layer QL), the band structure changes as illustrated in FIG. 4, and a conduction band minimum (CBM) of the charge transport layer T2 (ETL) approaches the bulk state (becomes far from the vacuum level 0), thereby expanding an electron injection barrier Eb. Further, when the quantum dots QD are used in the light-emitting layer EM, electrons generally become excessive. Those two actions both act in a direction of suppressing the injection of electrons from the second electrode D2 (cathode) into the light-emitting layer EM. As a result, the carrier balance in the light-emitting element 10 is improved, and the external quantum efficiency (EQE) is improved as indicated by the solid line in FIG. 5.

In FIG. 4, the electron injection barrier Eb is a gap between a conduction band minimum of the quantum dot QD (CBMq) and a conduction band minimum of the ETL (nanoparticle NP) (CBMp). CBMq and CBMp are negative values (unit: eV) when the vacuum level is regarded as a reference (0). By increasing the average particle diameter Pa of the nanoparticles NP (causing the state thereof to approach the bulk state), CBMp becomes deeper and the electron injection barrier Eb is expanded.

In the light-emitting element 10, the charge transport layer T2 includes a plurality of the nanoparticle layers NL, and each of the nanoparticle layers NL has substantially the same particle diameter distribution DP. Thus, the charge transport layer T2 can be formed by a single application of a solution and thermosetting (described later), and an adverse effect on the quantum dot layer QL, which is the lower layer, and the process cost are suppressed. Furthermore, since the areas of the upper and lower interfaces (surface areas on the D2 side and the EM side) of the charge transport layer T2 (ETL) are increased, the interlayer joining force is increased, and an occurrence of peeling and cracking is reduced.

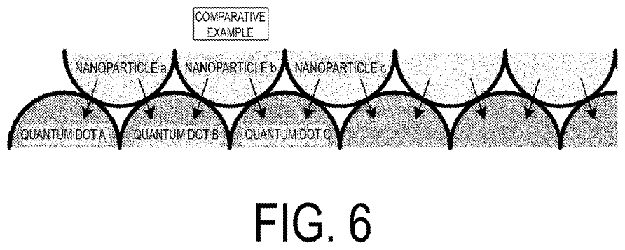

FIG. 6 is a schematic cross-sectional view illustrating actions of a light-emitting element according to a comparative example. In this comparative example, an average particle diameter of nanoparticles (a to c) is equal to or less than an average particle diameter of quantum dots (A to C), and charge transport paths (indicated by arrows in the drawing) via contact points between the nanoparticles and the quantum dots are formed. In FIG. 6, the nanoparticle a enters a gap between the quantum dot A and the quantum dot B that are adjacent to each other, and charge transport paths are formed from the nanoparticle a to the quantum dot A and the quantum dot B. Since the quantum dot B also has a contact point with the nanoparticle b, a charge transport path is also formed from the nanoparticle b to the quantum dot B.

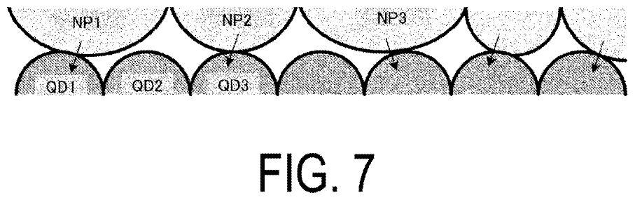

FIG. 7 is a schematic cross-sectional view illustrating actions of the light-emitting element according to the first embodiment. In the first embodiment, an average particle diameter of nanoparticles (NP1 to NP3) is larger than an average particle diameter of quantum dots (QD1 to QD3). Although charge transport paths (indicated by arrows in the drawing) are formed via contact points between the nanoparticles (NP1 to NP3) and the quantum dots (QD1 to QD3), the number of charge transport paths is smaller than that in the comparative example of FIG. 6. For example, the nanoparticle NP1 is in contact with only the quantum dot QD1 without entering a gap between the quantum dot QD1 and the quantum dot QD2 that are adjacent to each other. Therefore, a charge transport path is formed only from the nanoparticle NP1 to the quantum dot QD1. Similarly, the nanoparticle NP2 is in contact with only the quantum dot QD3 without entering a gap between the quantum dot QD2 and the quantum dot QD3 that are adjacent to each other. Therefore, a charge transport path is formed only from the nanoparticle NP2 to the quantum dot QD3. Note that since the quantum dot QD2 has no contact point with any of the nanoparticles, a charge transport path to the quantum dot QD2 is not formed.

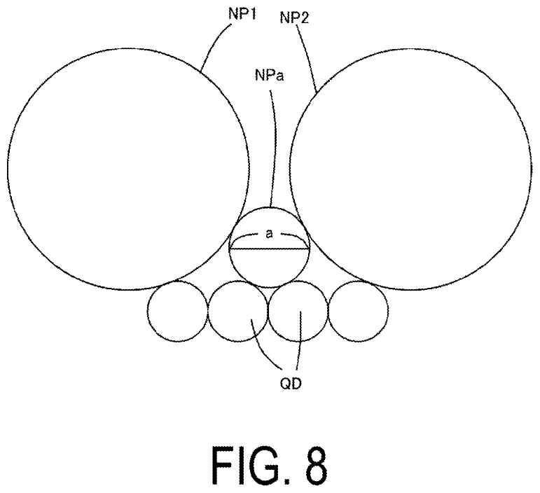

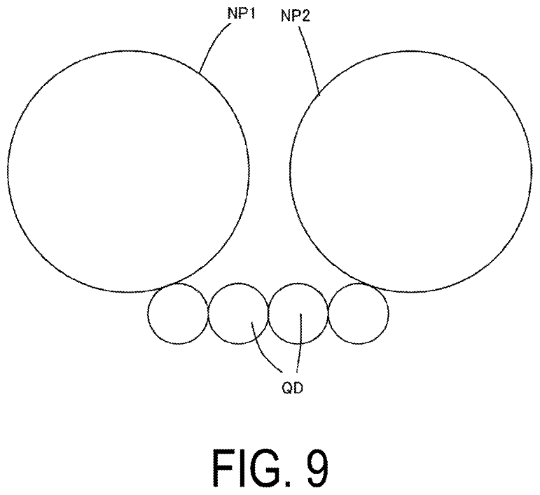

FIG. 8 and FIG. 9 are cross-sectional views illustrating configuration examples of the light-emitting element according to the first embodiment. In FIG. 8, a small nanoparticle NPa having a particle diameter a equal to or less than ½ of an average particle diameter of the nanoparticles (NP1 and NP2) is included. In this case, since the small nanoparticle NPa enters a gap between the nanoparticles NP1 and NP2 that are adjacent to each other, charge transport paths are formed between the nanoparticles NP1 and NP2 and the quantum dots QD via the nanoparticle NPa. In FIG. 9, since the small nanoparticle having the particle diameter equal to or less than ½ of the average particle diameter of the nanoparticles (NP1 and NP2) is not included, the number of contact points between the nanoparticles NP1 and NP2 and the quantum dots QD can be reduced. In other words, the particle diameter lower limit value Pk of the nanoparticles NP included in the nanoparticle layer NL is desirably equal to or greater than ½ of the average particle diameter Pa of the nanoparticles NP.

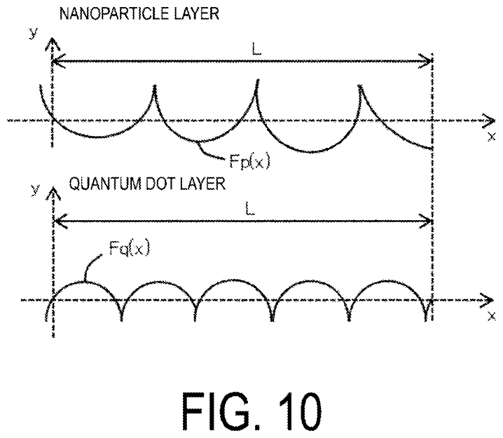

FIG. 10 is a schematic view illustrating surface roughnesses of the nanoparticle layer and the quantum dot layer. Since the interface between the quantum dot layer QL and the nanoparticle layer NL becomes non-uniform, the number of charge transport paths from the charge transport layer T2 to the light-emitting layer EM can be reduced. For example, when the surface roughness of the quantum dot layer QL is equal to or greater than a certain level, it may be regarded that the interface between the quantum dot layer QL and the nanoparticle layer NL is not uniform. For example, while taking into account the fact that the surface roughness of the nanoparticle layer NL tends to be defined depending on the surface roughness of the quantum dot layer QL, the surface roughness at the interface between the quantum dot layer QL and the nanoparticle layer NL may be calculated as a root mean square roughness of the surface of the quantum dot layer QL. The root mean square roughness (Rms) of the quantum dot layer QL is preferably 2.5 nm or greater.

Not being limited to the above, the interface between the nanoparticle layer NL and the quantum dot layer QL may be regarded as non-uniform when the root mean square roughness (Rms) of the surface of the nanoparticle layer NL is equal to or greater than 2.5 nm.

Note that, in a cross section of the ETL captured by the TEM or the like, the root mean square roughness (Rms) of the nanoparticle layer can be calculated as a square root of an average value obtained by integrating, by a unit length L, a square of a roughness curve y=Fp(x) taking an average line as the x-axis thereof, and dividing the integrated value by L. In a cross section of the light-emitting layer captured by the TEM or the like, the root mean square roughness (Rms) of the quantum dot layer QL can be calculated as a square root of an average value obtained by integrating, by the unit length L, a square of a roughness curve y=Fq(x) taking an average line as the x-axis thereof, and dividing the integrated value by L.

In addition, when the average particle diameter Qa of the quantum dots QD included in the quantum dot layer QL and the average particle diameter Pa of the nanoparticles NP included in the nanoparticle layer NL satisfy Pa≥Qa, by setting the surface roughness (Rms) of the nanoparticle layer NL to be greater than the surface roughness (Rms) of the quantum dot layer QL, the surface area of the nanoparticle layer NL on the quantum dot layer QL side is increased, and as a result, the interface between the nanoparticle layer NL and the quantum dot layer QL becomes non-uniform. Further, if the nanoparticle layer on the second electrode D2 side is formed in the same manner, the surface area on the second electrode D2 side can also be increased.

With the configuration described above, the interface between the quantum dot layer QL and the nanoparticle layer NL becomes non-uniform, and thus, the number of charge transport paths from the charge transport layer T2 to the light-emitting layer EM can be reduced, and the carrier balance can be improved.

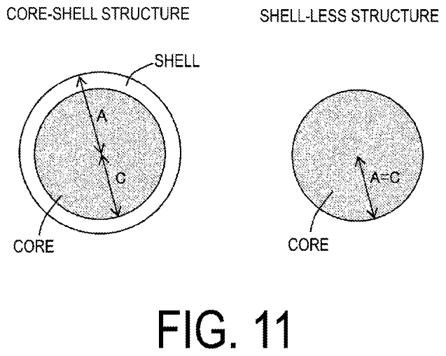

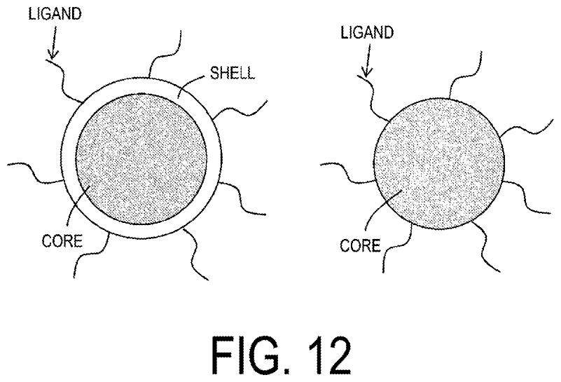

FIG. 11 and FIG. 12 are schematic views illustrating configuration examples of the quantum dot. As illustrated in FIG. 11, the quantum dot QD may have a core-shell structure (particle diameter A>core diameter C) or a shell-less structure (no shell is present and the core is exposed) (particle diameter A=core diameter C). When the quantum dot QD has the core-shell structure, surface defects are reduced, and non-emitting recombination at the defect level is less likely to occur. As a result, the luminous efficiency is improved. Note that the shell is not necessarily required to completely cover the core, and may be formed so as to cover a portion of the core.

As illustrated in FIG. 12, a ligand may be disposed at the surface of the quantum dot QD. By disposing the ligand at the quantum dot QD, dispersibility of the quantum dot QD in a solution is enhanced, and surface defects are inactivated. Note that when the light-emitting layer EM includes the quantum dot QD and a compound that can serve as the ligand, it can be regarded that the ligand is adsorbed (coordinated) to the surface of the quantum dot QD.

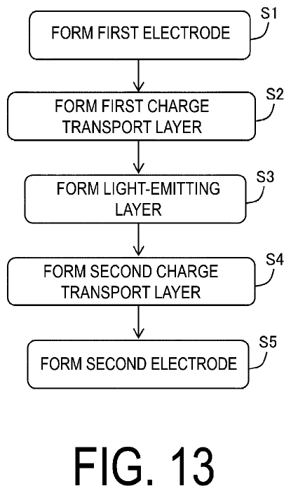

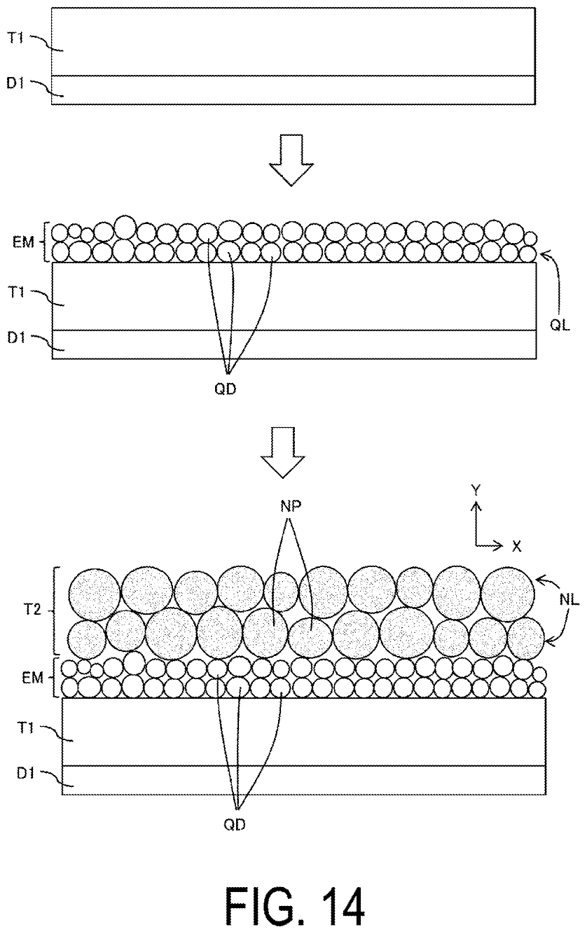

FIG. 13 is a flowchart illustrating a manufacturing method of the light-emitting element according to the first embodiment. FIG. 14 is a set of cross-sectional views each illustrating the manufacturing method of the light-emitting element according to the first embodiment. In FIG. 13, the first electrode D1 is formed at step S1, the first charge transport layer T1 is formed at step S2, the light-emitting layers EM is formed at step S3, the second charge transport layer T2 is formed at step S4, and the second electrode D2 is formed at step S5. A hole transport layer (HTL) may be formed at step S2, and an electron transport layer (ETL) may be formed at step S4 (when a sequential structure is adopted). The ETL may be formed at step S2, and the HTL may be formed at step S4 (when a reverse structure is adopted).

When the sequential structure is adopted, at step S2, for example, a process is performed in which a solution obtained by dispersing poly(N,N′-bis(4-butylphenyl)-N,N′-bisphenylbenzidine) (poly-TPD), which is an HTL material, in a chlorobenzene solvent is applied, and the solvent is removed. A hole injection layer (including, for example, NiO, poly(3,4-ethylenedioxythiophene) polystyrene sulfonate (PEDOT:PSS), or MoO₃) may be formed between step S1 and step S2.

At step S3, for example, as illustrated in FIG. 14, a process is performed in which a solution including the quantum dots QD and a solvent (for example, octane) is applied onto the first charge transport layer T1 (HTL), and the solvent is removed. As a result, the light-emitting layer EM including the quantum dot layer QL is formed.

At step S4, a process is performed in which a solution (nanoparticle solution) obtained by dispersing the nanoparticles NP (for example, ZnO nanoparticles that are an ETL material) having an average particle diameter greater than that of the quantum dots QD in a solvent (ethanol, methanol, isopropyl alcohol (IPA), octane, dimethyl sulfoxide (DMSO), dimethylformamide (DMF), water, or the like) is applied onto the light-emitting layer EM, and the solvent is removed. As a result, a plurality of the nanoparticle layers NL having the same particle diameter distribution are formed. Since the average particle diameter of the nanoparticles NP does not change in a thickness direction (y-direction) in the charge transport layer T2, the charge transport layer T2 can be formed by a single application of a solution and thermosetting.

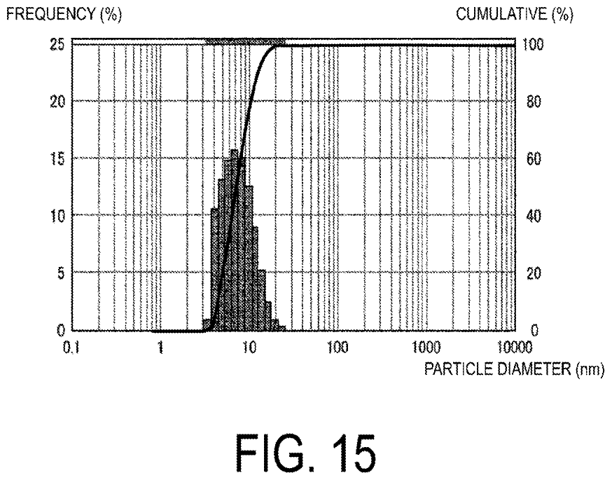

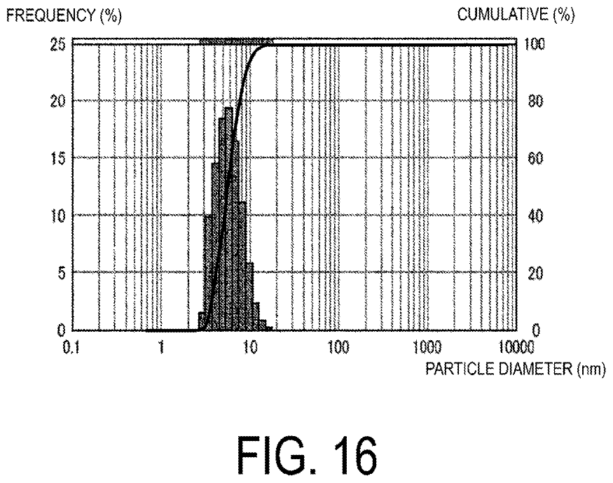

FIG. 15 and FIG. 16 are graphs each showing an example of the particle diameter distribution in a nanoparticle solution. In a nanoparticle solution of FIG. 15, it can be seen that the particle diameter distribution of the nanoparticles has the particle diameter lower limit value Pk of 3.2 (nm), the average particle diameter Pa of 7.9 (nm), and the standard deviation Pa of 3.5 (nm). In a nanoparticle solution of FIG. 16, it can be seen that the particle diameter distribution of the nanoparticles has the particle diameter lower limit value Pk of 2.8 (nm), the average particle diameter Pa of 6.5 (nm), and the standard deviation Pa of 2.4 (nm). When the average particle diameter of the quantum dots QD in the quantum dot layer QL is 7.5 (nm) or less, the nanoparticle solution of FIG. 15 may be used. When the average particle diameter of the quantum dots QD in the quantum dot layer QL is 6.0 (nm) or less, the nanoparticle solution of FIG. 16 may be used.

### Second Embodiment

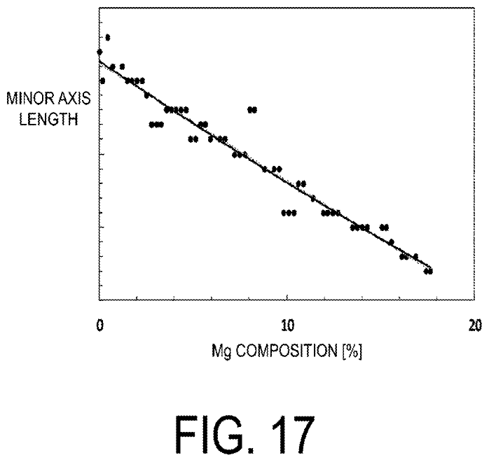

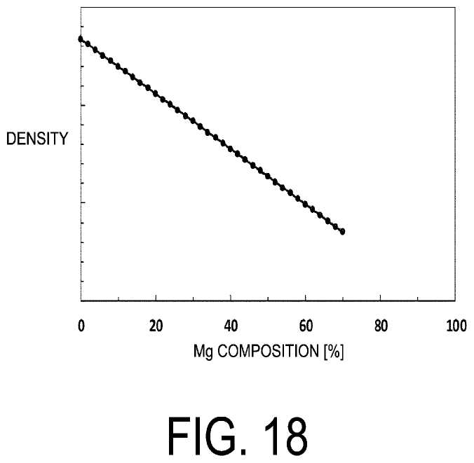

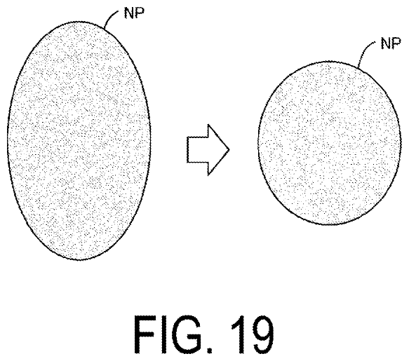

FIG. 17 is a graph showing a relationship between the Mg composition and the minor axis (C-axis) in zinc magnesium oxide nanoparticles. FIG. 18 is a graph showing a relationship between the Mg composition and the density in the zinc magnesium oxide nanoparticles. FIG. 19 is a schematic view illustrating a change in the shape of the zinc magnesium oxide nanoparticle when the magnesium composition is increased. From FIG. 17 to FIG. 19, it can be seen that, in the zinc magnesium oxide nanoparticles, by increasing the Mg composition, the minor axis (C-axis) is increased (becomes closer to a true spherical shape from an ellipsoidal shape), and the density is significantly reduced (from 5.68 g/cm³ to around 3.25 g/cm³).

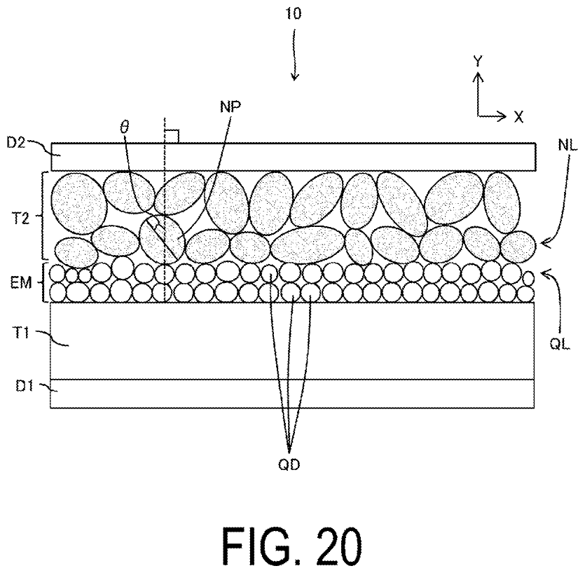

FIG. 20 is a cross-sectional view illustrating a configuration example of a light-emitting element according to a second embodiment. In the light-emitting element 10, the nanoparticles NP may be zinc magnesium oxide (mixed crystal) including Zn and Mg, or the nanoparticles NP may have shape anisotropy, for example, may have a rotational body shape (for example, an ellipsoidal shape) including a major axis and a minor axis. The composition ratio (molar ratio) of Mg with respect to Zn may be 0.015 (composition ratio of Mg being 0.6%) to 1.5 (composition ratio of Mg being 60%). The density of the nanoparticles NP can be reduced by causing the nanoparticles NP to contain Mg, which is a light element.

When a solution is applied that includes low-density zinc magnesium oxide nanoparticles, due to a decrease in the inertial force and to an increase in the viscous resistance with the solvent caused by an increased size of the nanoparticle, the nanoparticles NP become inclined (enter into a fallen-over state) so that an angle between the major axis and the thickness direction of the underlayer (the light-emitting layer EM) increases, and thus become more attachable. Further, the major axis can freely rotate in the plane. These are phenomena specific to the nanoparticles NP capable of realizing the shape anisotropy and the low density at the same time, and both have an effect of reducing the number of contact points (electron transport paths) between the nanoparticle layer NL and the quantum dot layer QL at the interface between the two layers. As a result, the carrier balance of the light-emitting element 10 is improved, and the EQE is improved.

Mg is used as the light element here, but the light element is not limited thereto, and lithium (Li), which is also a light element and can be substituted for Zn, may be used. In other words, the nanoparticle NP may be zinc lithium oxide (mixed crystal) including Zn and Li. The nanoparticle NP may be a mixed crystal of metal oxides including Zn, Mg and Li. As a light element other than Mg and Li, Na (sodium), K (potassium), or Ca (calcium) may be used.

As shown in FIG. 17, the nanoparticle layer NL may include the plurality of nanoparticles NP each having an angle θ (particle inclination angle) of 39° or greater formed between the major axis and the normal direction of the second electrode D2 (a thickness direction Y of the light-emitting layer EM). In this case, the number of contact points between both the layers (NL and QL) are effectively reduced, and the carrier balance is improved. In the nanoparticle layer NL, a ratio of the number of particles having the particle inclination angle θ of 45° or greater may be larger than a ratio of the number of particles having the particle inclination angle θ of less than 45°.

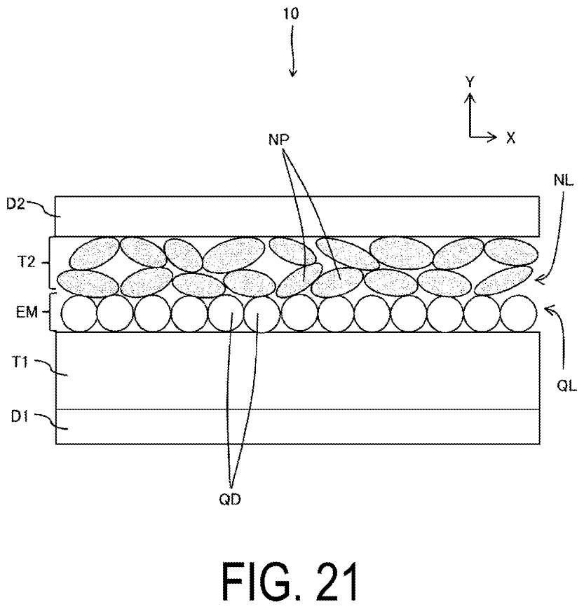

FIG. 21 is a cross-sectional view illustrating another configuration example of the light-emitting element according to the second embodiment. As illustrated in FIG. 21, when the nanoparticle NP has a longitudinal shape (for example, an ellipsoidal shape), the major axis size (=particle diameter) of the nanoparticle NP may be larger than the average particle diameter of the quantum dots QD, and the minor axis size of the nanoparticle NP may be smaller than the average particle diameter of the quantum dots QD. In this case also, the number of contact points between both the layers (NL and QL) are effectively reduced.

### Third Embodiment

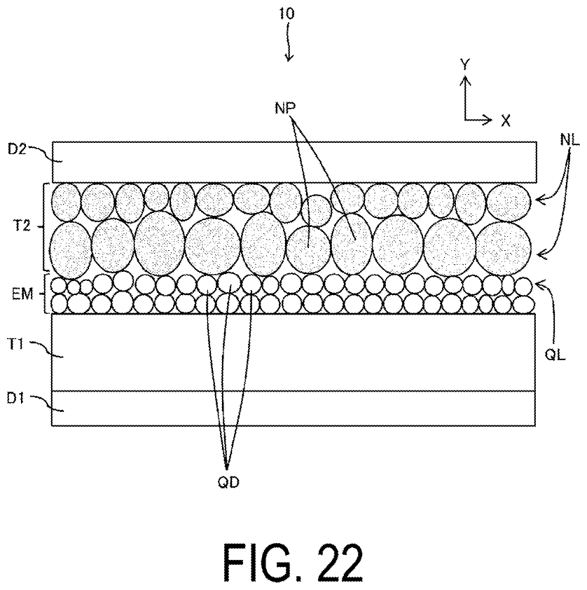

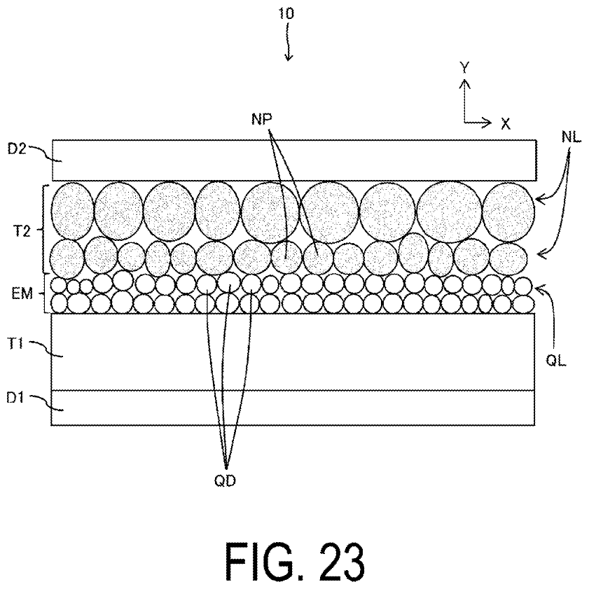

FIG. 22 and FIG. 23 are cross-sectional views each illustrating a configuration example of a light-emitting element according to a third embodiment. In the charge transport layer T2 (ETL) according to the first and second embodiments, a configuration is adopted in which the average particle diameter of the nanoparticles NP does not change in a layering direction of the nanoparticle layer (y direction), but the configuration is not limited to this example. As illustrated in FIG. 22, the average particle diameter of the nanoparticle layer NL adjacent to the quantum dot layer QL may be made larger than the average particle diameter of the nanoparticle layer NL adjacent to the second electrode D2. Further, as illustrated in FIG. 23, the average particle diameter of the nanoparticle layer NL adjacent to the quantum dot layer QL (larger than the average particle diameter of the quantum dots QD) may be made smaller than the average particle diameter of the nanoparticle layer NL adjacent to the second electrode D2.

### Fourth Embodiment

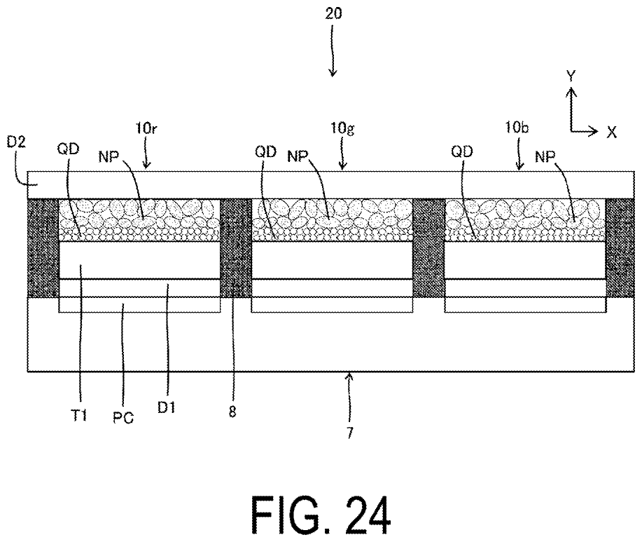

FIG. 24 is a cross-sectional view illustrating a configuration example of a display device according to a fourth embodiment. As illustrated in FIG. 24, a display device 20 includes a light-emitting element 10r that emits red light, a light-emitting element 10g that emits green light, and a light-emitting element 10b that emits blue light. The light-emitting elements 10r, 10g, and 10b are formed on a drive substrate 7 (for example, a pixel circuit substrate including a TFT), and are partitioned by insulating partition walls 8. Pixel circuits PC corresponding to each of the light-emitting elements 10r, 10g, and 10b are provided on the drive substrate 7.

In FIG. 24, the first electrode D1 may be an anode. The anode (D1) is formed individually (in an island shape) for each of the light-emitting elements. On the other hand, the charge function layer T1 (hole transport layer), the electron transport layer including the nanoparticles NP, and the cathode D2 may be formed commonly for the light-emitting elements 10r, 10g, and 10b.

The anode and the cathode may contain a conductive material, and at least one of them may be a transparent electrode. When the display device 20 is a single-sided display device, one of the anode and the cathode that is closer to a display surface (visually recognized surface) may be a transparent electrode, and the other electrode that is farther from the display surface may be a reflective electrode. When the display device 20 is a double-sided display device, both the anode and the cathode may be transparent electrodes. The transparent electrode can be formed from a light-transmissive conductive material. The reflective electrode can be formed from a light-reflective conductive material, and may be a layered body formed from a light-transmissive conductive material and a light-reflective conductive material.

The quantum dots QD of the light-emitting elements 10r, 10g, and 10b may have different core particle diameters, and core materials thereof may be different from each other. The band gap of the quantum dot QD of the light-emitting element 10r may be smaller than the band gap of the quantum dot QD of the light-emitting element 10g, and the band gap of the quantum dot QD of the light-emitting element 10g may be smaller than the band gap of the quantum dot QD of the light-emitting element 10b. In FIG. 24, the light-emitting elements 10 according to the second embodiment are applied as the light-emitting elements 10r, 10g, and 10b, but the configuration is not limited to this example. The light-emitting element 10 according to any one of the first to third embodiments may be applied.

The embodiments described above are for the purpose of illustration and description and are not intended to be limiting. It will be apparent to those skilled in the art that many variations will be possible in accordance with these examples and descriptions.

1-7. (canceled)

8. A light-emitting element comprising:
a first electrode;
a second electrode;
a light-emitting layer disposed between the first electrode and the second electrode; and
a charge function layer disposed between the light-emitting layer and the second electrode,
wherein the light-emitting layer includes a quantum dot layer including a plurality of quantum dots,
the charge function layer includes a nanoparticle layer including a plurality of nanoparticles, and
a root mean square surface roughness of the nanoparticle layer or a root mean square surface roughness of the quantum dot layer is 2.5 nm or greater.

9. The light-emitting element according to claim 8,
wherein each of the plurality of nanoparticles is composed of a metal oxide.

10. The light-emitting element according to claim 9,
wherein the metal oxide contains one or more metal elements selected from Group I and Group II.

11. The light-emitting element according to claim 8,
wherein the nanoparticle layer includes a nanoparticle among the plurality of nanoparticles, the nanoparticle having a minor axis and a major axis and having a particle diameter equivalent to a size of the major axis.

12. The light-emitting element according to claim 11,
wherein a size of the minor axis is smaller than the average particle diameter of the plurality of quantum dots.

13. The light-emitting element according to claim 11,
wherein the major axis is inclined with respect to a normal direction of the second electrode.

14. The light-emitting element according to claim 13,
wherein the major axis is inclined at 39° or more with respect to the normal direction of the second electrode.

15. The light-emitting element according to claim 8,
wherein a crystal structure of each of the plurality of nanoparticles is cubic or hexagonal.

16. The light-emitting element according to claim 8,
wherein the nanoparticle layer includes a spherical nanoparticle among the plurality of nanoparticles.

17. The light-emitting element according to claim 9,
wherein each of the plurality of nanoparticles contains zinc.

18. The light-emitting element according to claim 17,
wherein each of the plurality of nanoparticles contains at least one of magnesium and lithium.

19. The light-emitting element according to claim 18,
wherein a composition ratio of magnesium to zinc in each of the plurality of nanoparticles is 0.015 to 1.5.

20. The light-emitting element according to claim 8,
wherein the charge function layer is an electron transport layer.

21. The light-emitting element according to claim 8,
wherein the nanoparticle layer is formed as a layer above the quantum dot layer.

22. The light-emitting element according to claim 13,
wherein, in the nanoparticle layer, a number ratio of nanoparticles having an inclination angle of 45° or more with respect to the normal direction is larger than a number ratio of nanoparticles having an inclination angle of less than 45° with respect to the normal direction.

23. (canceled)

24. A light-emitting element comprising:
a first electrode;
a second electrode;
a light-emitting layer disposed between the first electrode and the second electrode; and
a charge function layer disposed between the light-emitting layer and the second electrode,
wherein the light-emitting layer includes a quantum dot layer including a plurality of quantum dots,
the charge function layer includes a nanoparticle layer including a plurality of nanoparticles,
an average particle diameter of the plurality of nanoparticles is larger than an average particle diameter of the plurality of quantum dots, and
Pσ>Pa/4 is satisfied,
where, for the plurality of nanoparticles, the average particle diameter is denoted by Pa and a standard deviation of a particle diameter is denoted by Pσ.

25. The light-emitting element according to claim 24,
wherein Pσ/Pa>Qσ/Qa is satisfied,
where, for the plurality of nanoparticles, the average particle diameter is denoted by Pa and a standard deviation of a particle diameter is denoted by Pσ, and, for the plurality of quantum dots, the average particle diameter is denoted by Qa, and a standard deviation of a particle diameter is denoted by Qσ.

26. The light-emitting element according to claim 24,
wherein a lower limit of a particle diameter distribution of the nanoparticle layer is 0.5×Pa,
where the average particle diameter of the plurality of nanoparticles is denoted by Pa.

27. A light-emitting element comprising:
a first electrode;
a second electrode;
a light-emitting layer disposed between the first electrode and the second electrode; and
a charge function layer disposed between the light-emitting layer and the second electrode,
wherein the light-emitting layer includes a quantum dot layer including a plurality of quantum dots,
the charge function layer includes a nanoparticle layer including a plurality of nanoparticles,
an average particle diameter of the plurality of nanoparticles is larger than an average particle diameter of the plurality of quantum dots, and
Pσ/Pa>Qσ/Qa is satisfied,
where, for the plurality of nanoparticles, the average particle diameter is denoted by Pa and a standard deviation of a particle diameter is denoted by Pσ, and, for the plurality of quantum dots, the average particle diameter is denoted by Qa, and a standard deviation of a particle diameter is denoted by Qσ.

28. The light-emitting element according to claim 27,
wherein a lower limit of a particle diameter distribution of the nanoparticle layer is 0.5×Pa,
where the average particle diameter of the plurality of nanoparticles is denoted by Pa.
